(19) United States
(12) Patent Application Publication
(10) Pub. No.: US 2011/0159186 A1
(43) Pub. Date: Jun. 30, 2011

(54) FILM FORMING APPARATUS AND FILM FORMING METHOD

(75) Inventors: Andrew Chakchung Yu, Miyagi (JP); Takahiro Kawana, Miyagi (JP); Hidetoshi Honda, Miyagi (JP); Seiichi Onodera, Miyagi (JP); Yohei Kanno, Miyagi (JP)

(73) Assignee: SONY CORPORATION, Tokyo (JP)

(21) Appl. No.: 12/975,492

(22) Filed: Dec. 22, 2010

(30) Foreign Application Priority Data
Dec. 28, 2009 (JP) P2009-298104

(51) Int. Cl. C23C 16/458; C23C 16/00; C23C 16/44

(52) U.S. Cl. 427/255.5; 118/718

(57) ABSTRACT

The present invention provides a film forming apparatus and a film forming method realizing improvement in the degree of freedom in film formation while suppressing production cost. While conveying a base material by using a plurality of guide rolls, film formation is performed by atomic layer deposition by outputting precursor gases to the base material by a plurality of ALD heads. The ALD heads are disposed so as to individually face the guide rolls so that the precursor gases are locally output to the base material. The amount of the precursor gases used is reduced more than that in a related art, and the variety of kinds of the usable precursor gases is widened.

### CROSS REFERENCES TO RELATED APPLICATIONS

The present application claims priority to Japanese Priority Patent Application JP 2009-298104 filed in the Japan Patent Office on Dec. 28, 2009, the entire content of which is hereby incorporated by reference.

### BACKGROUND

The present application relates to a film forming apparatus and a film forming method using ALD (Atomic Layer Deposition).

The ALD for forming a thin film by sequentially outputting a material gas (precursor gas) which is chemically active to a base material (base) is previously used as a method of forming a thin film (refer to, for example, Japanese Unexamined Patent Application Publication (Translation of PCT Application) No. 2007-516347). In the ALD, for example, by alternately exposing the base material with two kinds of precursor gases, a monolayer is formed in each cycle.

Such ALD has, for example, the following advantages. First, a thin film of high quality is controlled in very small thickness in the order of about 0.1 nm. A structure in the micro or nano order having a very high aspect ratio is obtained. A film is formed without using a very high vacuum environment.

### SUMMARY

In a method other than the ALD, the rate of forming a thin film (film growth speed per unit time) is controlled according to the density of particles flying to a substrate, so that the film deposition rate is determined by power (input energy) of a reaction head, shortening of the distance between substrates, or the like. On the other hand, in the ALD, the film formation rate is determined only by the number of times of passage through a reaction head (ALD head) (because the thickness of a film deposited per time is determined). To be specific, in the film forming method using the ALD (particularly, the previous ALD technique which does not use the following roll-to-roll method), the film formation rate is determined by whether gas is quickly exchanged or not. In other words, in the conventional film forming method using the ALD, the above-described two kinds of precursor gases are alternately charged to and exhausted from a single chamber. There is consequently a problem that film formation time as a whole is very long.

To address the problem, film formation by the ALD using, for example, the roll-to-roll method is considered. Specifically, the method is, for example, a method of sequentially outputting precursor gases from their gas sources to a film-shaped or sheet-shaped base material having flexibility while conveying the base material by using a feed roll, a take-up roll, a guide roll, or the like.

In the case of forming a film by the ALD by using the above-described method, it may be unnecessary to change the precursor gas in the chamber. It is therefore considered that the film formation time is largely shortened as compared with the related art, and the manufacture efficiency improves. Since it may be unnecessary to fill a large chamber with the precursor gas, the amount of the precursor gases used is also reduced as compared with the related art. In other words, according to the method, the production cost at the time of film formation is suppressed more than that of the related art.

However, since various thin films can be obtained by applying the ALD, for example, the precursor gas may be used under various parameters including temperature, and it is therefore desired to improve the degree of freedom in film formation.

It is therefore desirable to provide a film forming apparatus and a film forming method realizing improved degree of freedom in film formation while suppressing production cost.

A film forming apparatus according to an embodiment of the invention includes: a conveying mechanism including a plurality of roll members and conveying a base material as a member on which a film is to be formed; and a plurality of heads disposed so as to individually face the roll members and each serving as a gas source capable of locally outputting a precursor gas for performing atomic layer deposition (ALD) to the base material.

A film forming method according to an embodiment of the invention forms a film by atomic layer deposition (ALD) by, while conveying a base material as a member on which a film is to be formed by using a plurality of roll members, locally outputting a precursor gas to the base material by a plurality of heads as gas sources disposed so as to individually face the roll members.

In the film forming apparatus and the film forming method according to embodiments of the invention, while conveying the base material as a member on which a film is to be formed by using the plurality of roll members, film formation by the atomic layer deposition by outputting the precursor gas to the base material by the plurality of heads as gas sources. Since the heads are disposed so as to individually face the roll members, the precursor gas is locally output to the base material. Therefore, the amount of the precursor gas used is smaller than that of the related art. For example, since the temperature of each of heads is individually adjustable, the variety of kinds of usable precursor gases is widened.

According to the film forming apparatus and the film forming method as embodiments, while conveying a base material by using a plurality of roll members, film formation by the atomic layer deposition is performed by outputting the precursor gas to a base material by a plurality of heads. In addition, by disposing the heads so as to individually face the roll members, the precursor gas is locally output to the base material. Therefore, the amount of the precursor gas used is made smaller than that of the related art, and the variety of kinds of the usable precursor gases is widened. Therefore, while suppressing production cost, the degree of freedom in film formation (easiness of designing/controlling of the structure, shape, material, and thickness of a layer to be formed, line speed, and the like) may be improved. Also in the roll-to-roll technique, the number of times of passing through the heads may be increased. Not only the number of heads is simply increased but a film forming apparatus in which, without replacing the roll members, switching of directions (forward and reverse directions) is easy is realized. Consequently, the number of passing times of the heads is increased and film formation speed which is competitive to methods other than the ALD is realized by an ALD film forming apparatus.

Additional features and advantages are described herein, and will be apparent from the following Detailed Description and the figures.

### BRIEF DESCRIPTION OF THE FIGURES

FIG. 1 is a schematic diagram illustrating a schematic configuration of a film forming apparatus according to a first embodiment.

FIGS. 2A to 2D are cross sections illustrating principle steps in a film forming method using the film forming apparatus shown in FIG. 1.

FIG. 3 is a schematic diagram illustrating a schematic configuration of a film forming apparatus according to a modification of the first embodiment.

FIG. 4 is a schematic diagram illustrating a schematic configuration of a film forming apparatus according to another modification of the first embodiment.

FIG. 5 is a schematic diagram illustrating a schematic configuration of a film forming apparatus according to a second embodiment.

FIGS. 6A to 6D are cross sections illustrating principle steps in a film forming method using the film forming apparatus shown in FIG. 5.

FIG. 7 is a schematic diagram illustrating a schematic configuration of a film forming apparatus according to a modification of the second embodiment.

FIG. 8 is a schematic diagram illustrating a schematic configuration of a film forming apparatus according to a third embodiment.

FIG. 9 is a schematic diagram illustrating a schematic configuration of a film forming apparatus according to a modification of the third embodiment.

FIG. 10 is a schematic diagram illustrating a schematic configuration of a film forming apparatus according to another modification of the third embodiment.

FIG. 11 is a schematic diagram illustrating a schematic configuration of a film forming apparatus according to a fourth embodiment.

FIG. 12 is a schematic diagram illustrating a schematic configuration of a film forming apparatus according to a modification of the fourth embodiment.

### DETAILED DESCRIPTION

Embodiments of the present application will be described below in detail with reference to the drawings.

First embodiment (example 1 of forming a film on one side of a base material without an ALD head for purge gas)

Second embodiment (example of forming a film on both sides of a base material)

Third embodiment (example 2 of forming a film on one side of a base material with an ALD head for purge gas)

Fourth embodiment (example 3 of forming a film on one side of a base material, in which each of ALD heads outputs a plurality of kinds of gases)

### First Embodiment

Configuration of Film Forming Apparatus 1

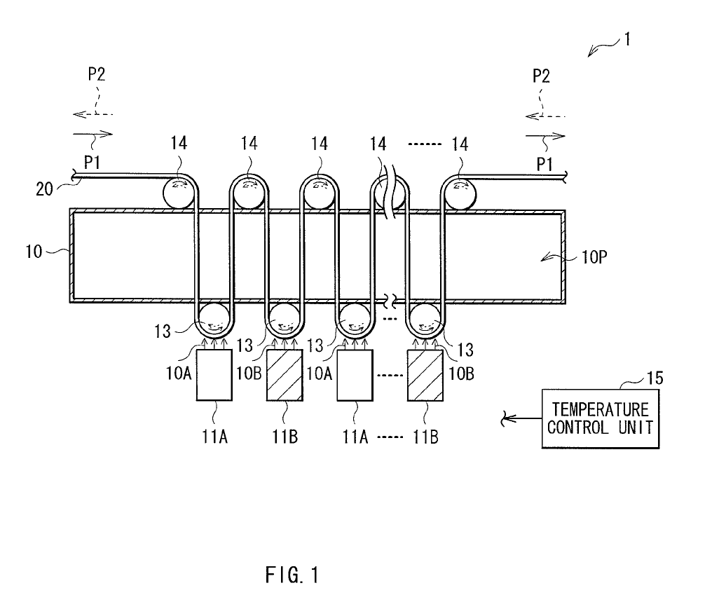

FIG. 1 illustrates a schematic configuration of a film forming apparatus (film forming apparatus 1) according to a first embodiment. The film forming apparatus 1 forms (manufactures) a desired thin film by performing film deposition by using the ALD on a base material 20 as a member to be coated. The film forming apparatus 1 has ALD heads (gas sources) 11A and 11B (heads), guide rolls 13 and 14 (roll members), a chamber 10, and a temperature control section 15. Since a film forming method (method for forming a thin film) according to the first embodiment of the invention is embodied in the film forming apparatus 1 of the embodiment, it will be also described below.

As the base material 20, it is preferable to use, for example, a film or sheet having flexibility. Examples of the material of the base material 20 include films of resins such as polyethylene terephthalate (PET), polyethylene naphthalate (PEN) polycarbonate (PC), polyethersulfone (PES), polystyrene (PS), aramid, triacetyl cellulose (TAC), cycloolefin polymer (COP), and polymethyl methacrylate (PMM). Examples of COP include ZEONOR (registered trademark of Zeon Corporation) and ARTON (registered trademark of JSR Corporation). Other examples of the base material 20 include metal films of aluminum, SUS, Ti, and the like and a flexible glass.

The ALD head 11A is a gas source capable of outputting a material gas (precursor gas) 10A for performing atomic layer deposition (ALD) to the base material 20. The precursor gas 10A is output (injected) from a not-shown output nozzle.

On the other hand, the ALD head 11B is a gas source capable of outputting a material gas (precursor gas) 10B for performing the atomic layer deposition (ALD) to the base material. Like the ALD head 11A, the precursor gas 10B is output (injected) from a not-shown output nozzle.

In the case of forming a thin film made of aluminum oxide (Al₂O₃), for example, TMA (trimethyl aluminum (CH₃)₃Al) or the like may be used as the precursor gas 10A. In the case of forming a thin film made of aluminum oxide (Al₂O₃), for example, water (H₂O) or the like may be used as the precursor gas 10B.

Other than the above, for example, the following materials of the precursor gases 10A and 10B may be used.
bis(tert-butylimino) bis(dimethylamino) tungsten (VI); ((CH₃)₃CN)₂W(N(CH₃)₂)₂,
tris(tert-butoxy) silanol; ((CH₃)₃CO)₃SiOH,
diethyl zinc; (C₂H₅)₂Zn,
tris(diethylamide) (tert-butylimido) tantalum (V); ((CH₃)₃CNTa(N(C₂H₅)₂)₃,
tris(tert-pentoxy) silanol; (CH₃CH₂C(CH₃)₂O)₃SiOH,
trimethyl(methylcyclopentadienyl) platinum (IV); C₅H₄CH₃Pt(CH₃)₃,
bis(ethylcyclopentadienyl) ruthenium (II); C₇H₉RuC₇H₉,
(3-aminopropyl)trimethoxy silane; H₂N(CH₂)₃Si(OC₂H₅)₃,
silicon tetrachloride; SiCl₄,
titanium tetrachloride; TiCl₄,
titanium (IV) isopropoxide; Ti[(OCH)(CH₃)₂]₄,
tetrakis(dimethylamido)titanium (IV); [(CH₃)₂N]₄Ti,
tetrakis(dimethylamido)zirconium (IV); [(CH₃)₂N]₄Zr,
tris[N,N-bis(trimethylsilyl)amido]yttrium; [[(CH₃)₃Si]₂]N]₃Y

On one side of the chamber 10, a plurality of guide rolls 13 are provided along the extending direction of the chamber 10. On the other side of the chamber 10, a plurality of guide rolls 14 are provided along the extending direction of the chamber 10. By the guide rolls 13 and 14 and not-shown feed rolls and take-up rolls, a conveying mechanism for conveying the base material 20 in a direction indicated by an arrow P1 in FIG. 1 is constructed. By the conveying mechanism, the base material 20 may be conveyed in both directions indicated by arrows P1 and P2 in FIG. 1. In other words, the conveying mechanism may convey the base material 20 bidirectionally for the positions of the ALD heads 11A and 11B. The arrows in the solid lines illustrated in the guide rolls 13 and 14 in FIG. 1 indicate the rotation directions of the guide rolls 13 and 14 when the base material 20 is conveyed in the direction of the arrow P1. The arrows in broken lines indicate the rotation directions of the guide rolls 13 and 14 when the base material 20 is conveyed in the direction of the arrow P2.

In the embodiment, the ALD heads 11A and 11B are disposed so as to face the guide rolls 13. In other words, by the ALD head 11A or 11B and the guide roll 13, a member set (first member set) for outputting the precursor gas 10A or 10B to the face of one of the sides of the base material 20 and performing the atomic layer deposition is constructed. As the details will be described later, the precursor gases 10A and 10B are locally output to the base material 20.

The chamber 10 is disposed between the guide rolls 13 and the guide rolls 14 and stores therein a predetermined inactive gas (purge gas) 10P. In other words, the chamber 10 functions as a gas mechanism for exposing the base material 20 to the purge gas 10P between the operation of outputting the precursor gas 10A and the operation of outputting the precursor gas 10B by the ALD heads 11A and 11B.

In the case of forming a thin film of, for example, aluminum oxide (Al₂O₃), argon (Ar) or the like is used as such a purge gas 10P. Other examples of the purge gas 10P include nitrogen (N₂), hydrogen (H₂), oxygen (O₂), and carbon dioxide (CO₂).

The temperature control section 15 adjusts (sets) the temperature of each of the guide rolls 13. With the section 15, while adjusting the temperature of each of the guide rolls 13, film is deposited on the base material 20 by the atomic layer deposition.

Action and Effect of Film Forming Apparatus 1

Next, the action and effect of the film forming apparatus 1 of the embodiment will be described.

Operation of Film Forming Apparatus 1

In the film forming apparatus 1, as illustrated in FIG. 1, the base material 20 is sequentially conveyed to the positions of the ALD heads 11A and 11B by the conveying mechanism made by the guide rolls 13 and 14 and the like.

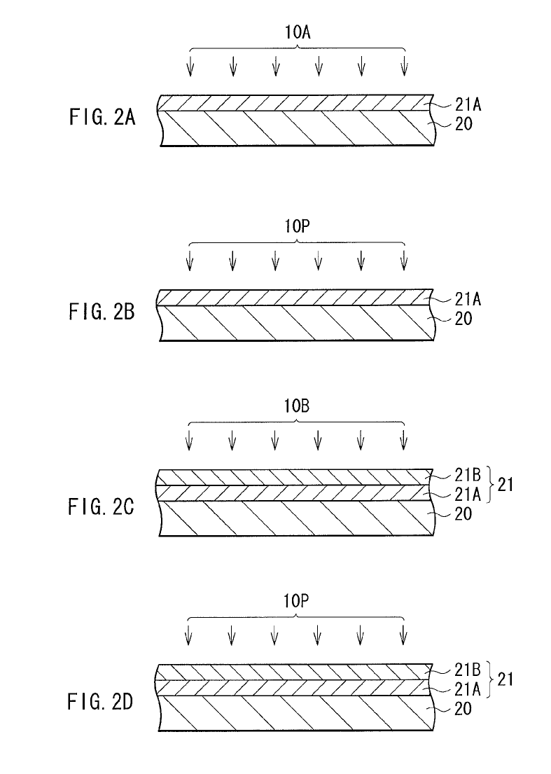

First, when the precursor gas 10A is output from the ALD heads 11A to the face (surface) on one side of the base material 20, as illustrated in FIG. 2A, a precursor layer 21A made by the precursor gas 10A is formed on the surface of the base material 20.

Subsequently, as illustrated in FIG. 1, the base material 20 on which the precursor layer 10A is formed is conveyed into the chamber 10.

As illustrated in FIG. 2B, the base material 20 is exposed to the purge gas 10P, and therefore the purge process is performed. Specifically, the unattached precursor gas 10A remaining on the base material 20 is removed from the surface of the precursor layer 21A.

Subsequently, as illustrated in FIG. 1, when the precursor gas 10B is output from the ALD heads 11B to the surface of the base material 20, a precursor layer 21B made of the precursor gas 10B is formed on the surface (on the precursor layer 21A) of the base material 20 as illustrated in FIG. 2C.

By the chemical reaction between the precursor layers 21A and 21B, a monolayer 21 as a component of a desired thin film is formed. In other words, a thin film is formed by the atomic layer deposition (ALD).

Thereafter, as illustrated in FIG. 1, the base material 20 on which the monolayer 21 is formed is conveyed into the chamber 10.

The base material 20 is then exposed to the purge gas 10P as illustrated in FIG. 2D, and therefore the purge process is performed again. In other words, the unattached precursor gas 10B remaining on the base material 20 is removed from the surface of the precursor layer 21B.

By repeating the operations illustrated in FIGS. 2A to 2D as a cycle, a desired thin film obtained by stacking the monolayers 21 is formed.

Action of Characteristic Part

In the film forming apparatus 1, while conveying the base material 20 as a material to be coated by using the plurality of guide rolls 13 and 14, the precursor gases 10A and 10B are output to the base material 20 by the plurality of ALD heads 11A and 11B as gas sources, thereby forming a film by the atomic layer deposition.

With the configuration, different from the film forming apparatus using the ALD as the related art, the process of replacing the precursor gas in the chamber may be unnecessary. Consequently, the film formation time is largely shortened and manufacture efficiency improves as compared with the related art.

Table 1 illustrates maximum line speed at the time of film formation in the film forming apparatus 1 of the embodiment in nine cases (calculation examples) (cases 1-1 to 1-9). The maximum line speed is specified by the following expression (1). Although the reaction time of the precursor gas in the expression (1) changes according to reaction temperature and the kind of the gas, three cases of 0.010, 0.015, and 0.020 are illustrated as an example. It is understood from Table 1 that the maximum line speed in the film forming apparatus 1 of the embodiment is a high value in the order of 10² m/minute.

Maximum line speed=(reaction time of precursor gas/output nozzle length of precursor gas along conveyance direction of base material) (1)

TABLE 1

| | | Output nozzle | | |
|---|---|---|---|---|
| | | length of | | |
| | | precursor gas | | |
| | | along | | |
| | Reaction | conveyance | | |
| Case | time | direction of | | |
| (calculation | of precursor | base material | Maximum line speed | |
| example) | gas (second) | (m) | (m/second) | (m/minute) |
| 1-1 | 0.020 | 0.1 | 5 | 300 |
| 1-2 | | 0.01 | 0.5 | 30 |
| 1-3 | | 0.001 | 0.05 | 3 |
| 1-4 | 0.015 | 0.1 | 6.667 | 400 |
| 1-5 | | 0.01 | 0.667 | 40 |
| 1-6 | | 0.001 | 0.067 | 4 |
| 1-7 | 0.010 | 0.1 | 10 | 600 |
| 1-8 | | 0.01 | 1 | 60 |
| 1-9 | | 0.001 | 0.1 | 6 |

Meanwhile, Table 2 illustrates film formation time by the ALD in the film forming apparatus 1 of the embodiment in four cases (calculation examples) (cases 2-1 to 2-4). The case of forming an Al₂O₃ thin film having a thickness of total 100 nm made by the precursor layers 21A and 21B each having a thickness of 0.1 nm on the face (surface) of one side of the base material 20 is illustrated here. The maximum line speed is 40 m/minute, and the length of the base material 20 is 1000 m. In other words, in the example, total 1,000 layers of the precursor layers 21A and 21B exist. In any of the cases 2-1 to 2-4, {(the number of ALD heads 11A)+(the number of the ALD heads 11B)}×(the number of passage times (the number of repetition times) of the roll-to-roll method)=1000. It is understood that, in proportion to the increase the number of passage times by the roll-to-roll method, time of the film formation by the ALD also increases by the amount.

TABLE 2

| | | | | Time of film |
|---|---|---|---|---|
| | | | | formation by |
| | | | The number of | ALD (minutes) |
| | | | passage times | (maximum line |
| | The | | by roll-to-roll | speed = 40 |
| | number of | The | method (the | (m/minute), |
| Case | ALD | number of | number of | length of base |
| (calculation | heads | ALD heads | repetition | material 20 = |
| example) | 11A | 11B | times) | 1000 (m)) |
| 2-1 | 500 | 500 | 1 | 25 |
| 2-2 | 50 | 50 | 10 | 250 |
| 2-3 | 25 | 25 | 20 | 500 |
| 2-4 | 10 | 10 | 50 | 1250 |

In the embodiment, the ALD heads 11A and 11B are disposed so as to individually face the guide rolls 13 and locally output the precursor gases 10A and 10B to the base material 20.

Since it may be unnecessary to fill a large chamber with the precursor gases unlike the related art, the amount of the precursor gases used is also reduced as compared with that in the related art. In other words, in addition to the above-described improvement in manufacture efficiency, in the embodiment, the production cost at the time of film formation is suppressed more than the related art.

Further, in the embodiment, the temperature control section 15 adjusts the temperature of each of the ALD heads 11A and 11B. Since the temperature at which a precursor gas is usable varies according to the kind of the gas, the variety of kinds of usable precursor gases is wider as compared with the related art.

In the embodiment as described above, while conveying the base material 20 by using the plurality of guide rolls 13 and 14, film formation is performed by the atomic layer deposition by outputting the precursor gases 10A and 10B to the base material 20 from the plurality of ALD heads 11A and 11B, and the ALD heads 11A and 11B are disposed so as to individually face the guide rolls 13, thereby locally outputting the precursor gases 10A and 10B to the base material 20. Therefore, the amount of the precursor gases 10A and 10B used is reduced more than that in the related art, and the variety of kinds of usable precursor gases is widened. Thus, while suppressing the production cost, the degree of freedom in film formation is improved.

Since the purge process is performed with the purge gas 10P stored in the chamber 10, the unattached precursor gases 10A and 10B remaining on the base material 20 are removed, and the reliability of the formed thin film is improved.

Modification of First Embodiment

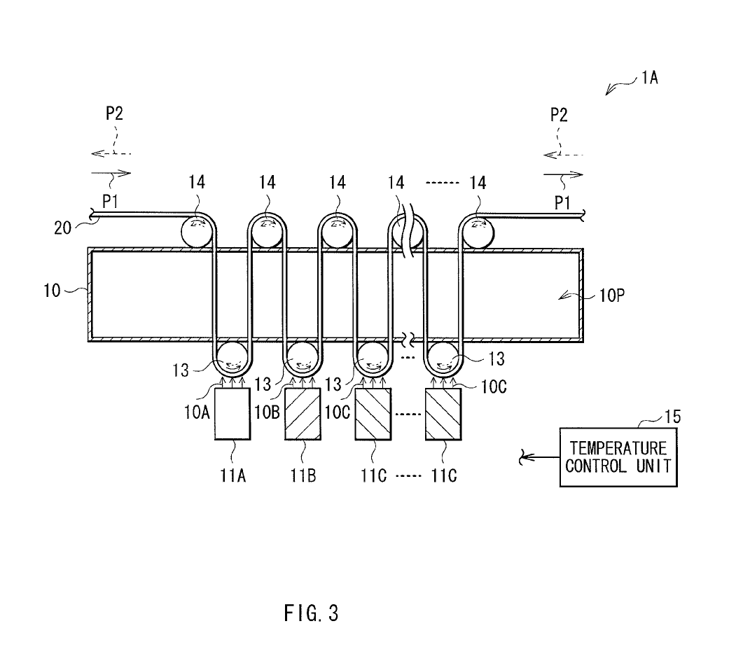

Although the case of performing the atomic layer deposition by the two kinds of precursor gases 10A and 10B using the two kinds of ALD heads 11A and 11B has been described in the embodiment, the invention is not limited to the case. For example, the atomic layer deposition may be performed with three or more kinds of precursor gases. Specifically, for example, like in a film forming apparatus 1A illustrated in FIG. 3, a desired thin film may be formed by performing the atomic layer deposition with three kinds of precursor gases 10A, 10B, and 10C using three kinds of ALD heads 11A, 11B, and 11C.

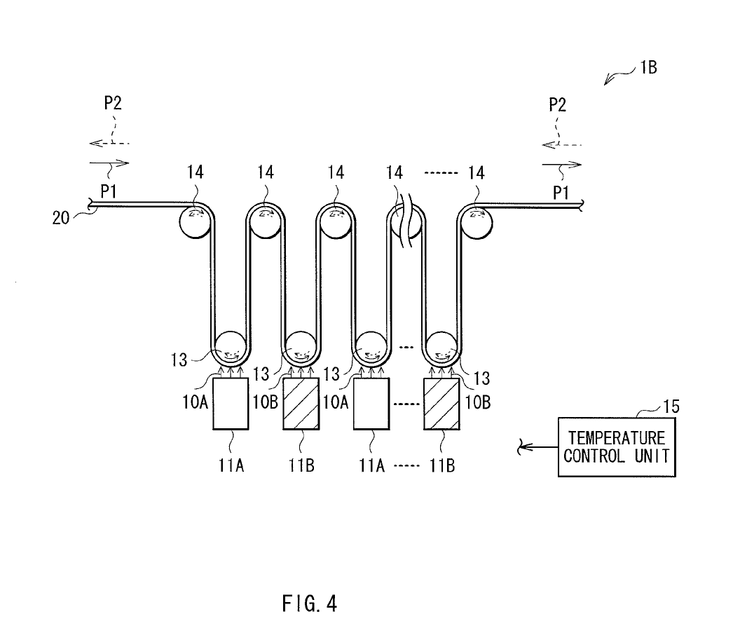

In the embodiment, the case where the purge gas is stored in the chamber 10 has been described. However, the invention is not limited to the case. The inside of the chamber 10 may be set in vacuum atmosphere or atmosphere which is the same as the normal outside air. Alternatively, for example, like a film forming apparatus 1B illustrated in FIG. 4, the chamber 10 itself may not be provided in some cases.

### Second Embodiment

Subsequently, a second embodiment of the invention will be described. The same reference numerals are designated to the same components as those of the foregoing first embodiment, and repetitive description will not be given.

Configuration of Film Forming Apparatus 1C

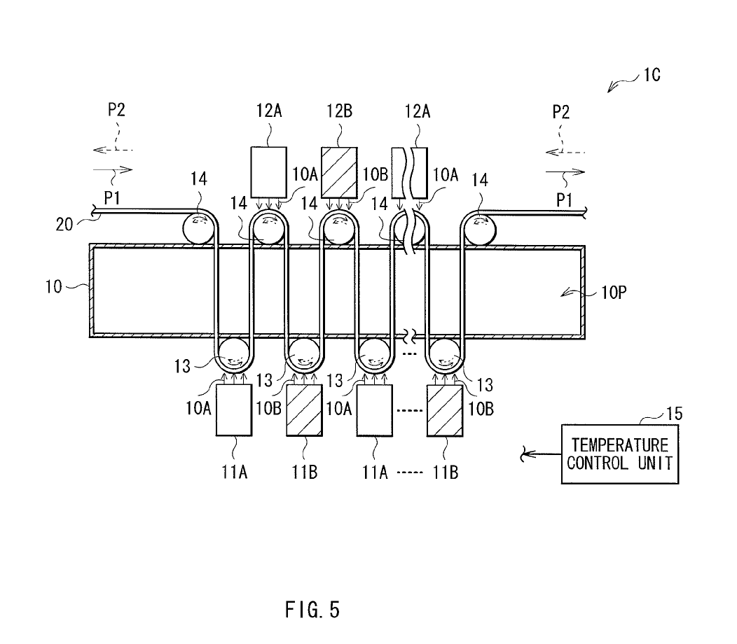

FIG. 5 illustrates a schematic configuration of a film forming apparatus (film forming apparatus 1C) according to a second embodiment. The film forming apparatus 1C is obtained by further providing ALD heads (gas sources) 12A and 12B to the film forming apparatus 1 of the first embodiment. As will be described below, a film is formed on both sides (surface and rear face) of the base material 20. Since the film forming method (thin film forming method) according to the second embodiment is embodied in the film forming apparatus 1C of the embodiment, it is also described below.

The ALD head 12A is, like the ALD head 11A, a gas source capable of outputting the precursor gas 10A for performing the atomic layer deposition to the base material 20, and outputs (injects) the precursor gas 10A from a not-shown output nozzle.

The ALD head 12B is, like the ALD head 11B, a gas source capable of outputting the precursor gas 10B for performing the atomic layer deposition to the base material 20, and outputs (injects) the precursor gas 10B from a not-shown output nozzle.

In the embodiment, in a manner similar to the first embodiment, the ALD heads 11A and 11B are disposed so as to individually face the guide rolls 13, and the ALD heads 12A and 12B are disposed so as to individually face the guide rolls 14. Specifically, by the ALD head 11A or 11B and the guide roll 13, a member set (first member set) for performing the atomic layer deposition by outputting the precursor gas 10A or 10B to the face (surface) of one of the sides of the base material 20 is constructed. By the ALD head 12A or 12B and the guide roll 14, a member set (second member set) for performing the atomic layer deposition by outputting the precursor gas 10A or 10B to the face (rear face) of the other side of the base material 20 is constructed. Also in the second embodiment, in a manner similar to the first embodiment, the precursor gases 10A and 10B are locally output to the base material 20.

In the embodiment, the temperature control section 15 adjusts (sets) the temperature of each of the guide rolls 13 and 14. While adjusting the temperature of each of the guide rolls 13 and 14, a film is deposited on the base material 20 by the atomic layer deposition.

Action and Effect of Film Forming Apparatus 1C

In the film forming apparatus 1C of the embodiment, as illustrated in FIG. 5, the base material 20 is sequentially conveyed to the positions of the ALD heads 11A, 11B, 12A, and 12B by the conveying mechanism made by the guide rolls 13 and 14 and the like.

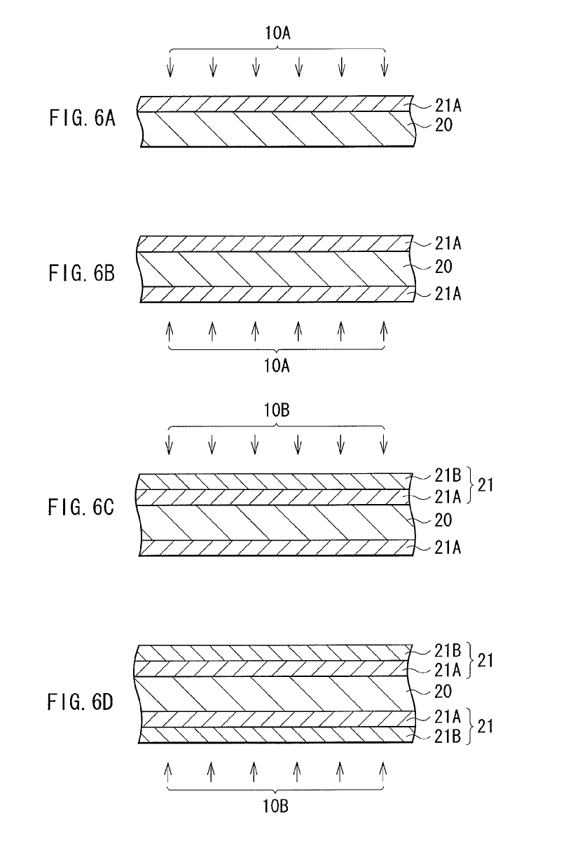

First, when the precursor gas 10A is output from the ALD heads 11A to the face (surface) on one side of the base material 20, as illustrated in FIG. 6A, in a manner similar to the first embodiment, the precursor layer 21A made by the precursor gas 10A is formed on the surface of the base material 20.

Subsequently, as illustrated in FIG. 5, the base material 20 on which the precursor layer 10A is formed is conveyed into the chamber 10. In a manner similar to the first embodiment, the base material 20 is exposed to the purge gas 10P, and therefore the purge process is performed. Specifically, the unattached precursor gas 10A remaining on the surface of the base material 20 is removed from the surface of the precursor layer 21A.

As illustrated in FIG. 5, when the precursor gas 10A is output from the ALD heads 12A to the face (rear face) on the other side of the base material 20, the precursor layer 21A made of the precursor gas 10A is formed on the rear face of the base material 20 as illustrated in FIG. 6B.

Subsequently, as illustrated in FIG. 5, the base material 20 on which the precursor layer 10A is formed is conveyed into the chamber 10. The base material 20 is exposed to the purge gas 10P, and therefore the purge process is performed again. Specifically, the unattached precursor gas 10A remaining on the rear face of the base material 20 is removed from the surface of the precursor layer 21A.

When the precursor gas 10B is output from the ALD head 11B to the surface of the base material 20 as illustrated in FIG. 5, the precursor layer 21B made of the precursor gas 10B is formed on the surface of the base material 20 (on the precursor layer 21A) as illustrated in FIG. 6C. By the chemical reaction between the precursor layers 21A and 21B, the monolayer 21 as a component of a desired thin film is formed on the surface of the base material 20. In other words, a thin film is formed on the surface of the base material 20 by the atomic layer deposition.

Thereafter, as illustrated in FIG. 5, the base material 20 on which the monolayer 21 is formed is conveyed again into the chamber 10. The base material 20 is exposed to the purge gas 10P, and therefore the purge process is performed again. In other words, the unattached precursor gas 10B remaining on the surface of the base material 20 is removed from the surface of the precursor layer 21B.

When the precursor gas 10B is output from the ALD head 12B to the rear face of the base material 20 as illustrated in FIG. 5, the precursor layer 21B made of the precursor gas 10B is formed on the rear face of the base material 20 (on the precursor layer 21A) as illustrated in FIG. 6D. By the chemical reaction between the precursor layers 21A and 21B, the monolayer 21 as a component of a desired thin film is formed on the rear face of the base material 20. In other words, a thin film is formed on the rear face of the base material 20 by the atomic layer deposition.

Thereafter, as illustrated in FIG. 5, the base material 20 on which the monolayer 21 is formed is conveyed again into the chamber 10. The base material 20 is exposed to the purge gas 10P, and therefore the purge process is performed again. In other words, the unattached precursor gas 10B remaining on the rear face of the base material 20 is removed from the surface of the precursor layer 21B.

By repeating the operations illustrated in FIGS. 6A to 6D as a cycle, a desired thin film obtained by stacking the monolayers 21 is formed on both sides (the surface and rear face) of the base material 20.

Tables 3 and 4 illustrate film formation time by the ALD in the film forming apparatus 1C of the embodiment in four cases (calculation examples) (cases 3-1 to 3-4 and cases 4-1 to 4-4).

Concretely, the cases 3-1 to 3-4 illustrated in Table 3 relate to examples of the case of forming an Al₂O₃ thin film having a thickness of total 50 nm made by the precursor layers 21A and 21B each having a thickness of 0.1 nm on both sides (the surface and rear face) of the base material 20. The maximum line speed is 40 m/minute, and the length of the base material 20 is 1000 m. In other words, in the example, total 1,000 layers of the precursor layers 21A and 21B exist. In any of the cases 3-1 to 3-4, {(the number of ALD heads 11A)+(the number of the ALD heads 11B)}×(the number of passage times of the roll-to-roll method)=1000 is satisfied. Like the cases 2-1 to 2-4 in the first embodiment, it is understood that, in proportion to the increase of the number of passage times (the number of repetition times) by the roll-to-roll method, time of the film formation by the ALD also increases by the amount.

TABLE 3

| | | | | Time of film |
|---|---|---|---|---|
| | | | | formation by |
| | | | The number of | ALD (minutes) |
| | | | passage times | (maximum line |
| | The | | by roll-to-roll | speed = 40 |
| | number | The | method (the | (m/minute), |
| Case | of ALD | number of | number of | length of base |
| (calculation | heads 11A | ALD heads | repetition | material 20 = |
| example) | and 12A | 11B and 12B | times) | 1000 (m)) |
| 3-1 | 500 | 500 | 1 | 25 |
| 3-2 | 50 | 50 | 10 | 250 |
| 3-3 | 25 | 25 | 20 | 500 |
| 3-4 | 10 | 10 | 50 | 1250 |

The cases 4-1 to 4-4 illustrated in Table 4 relate to examples of the case of forming an Al₂O₃ thin film having a thickness of total 100 nm made by the precursor layers 21A and 21B each having a thickness of 0.1 nm on both sides (the surface and rear face) of the base material 20. The maximum line speed is 40 m/minute, and the length of the base material 20 is 1000 m. In other words, in the example, total 2,000 layers of the precursor layers 21A and 21B exist. In any of the cases 4-1 to 4-4, {(the number of ALD heads 11A)+(the number of the ALD heads 11B)}×(the number of passage times of the roll-to-roll method)=2000 is satisfied. Like the cases 2-1 to 2-4 and the cases 3-1 to 3-4, it is understood that, in proportion to the increase of the number of passage times (the number of repetition times) by the roll-to-roll method, time of the film formation by the ALD also increases by the amount.

TABLE 4

| | | | | Time of film |
|---|---|---|---|---|
| | | | | formation by |
| | | | The number of | ALD (minutes) |
| | | | passage times | (maximum line |
| | The | | by roll-to-roll | speed = 40 |
| | number | The | method (the | (m/minute), |
| Case | of ALD | number of | number of | length of base |
| (calculation | heads 11A | ALD heads | repetition | material 20 = |
| example) | and 12A | 11B and 12B | times) | 1000 (m)) |
| 4-1 | 1000 | 1000 | 1 | 25 |
| 4-2 | 100 | 100 | 10 | 250 |
| 4-3 | 50 | 50 | 20 | 500 |
| 4-4 | 20 | 20 | 50 | 1250 |

Also in the embodiment as described above, similar effects are obtained by the action similar to that of the first embodiment. In other words, the amount of the precursor gases 10A and 10B used is also reduced as compared with that in the related art. In addition, the variety of kinds of usable precursor gases is wider and, while suppressing production cost, the degree of freedom in film formation is improved.

Particularly in the embodiment, by further providing the ALD heads 12A and 12B, film formation is performed by the atomic layer deposition on both sides (the surface and rear face) of the base material 20. Consequently, as compared with the case of performing film formation by the atomic layer deposition each time on the face on one side of the base material 20 like in the related art, the time of film formation on both faces is shortened. Since films are formed by the atomic layer deposition on both sides of the base material 20 simultaneously in parallel, shortening of the film formation time is realized. The thickness of each of the precursor layers formed on both sides of the base material 20 is properly adjusted by controlling the film formation time and the like of each of the ALD heads 12A and 12B. The thickness of each of the precursor layers formed on both sides of the base material 20 may be the same or different from each other.

Modification of Second Embodiment

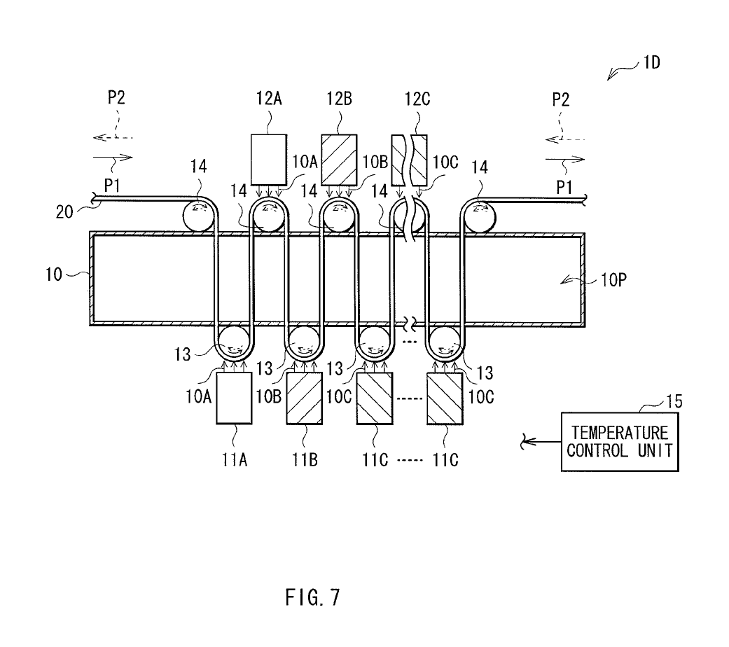

Also in the second embodiment, the atomic layer deposition may be performed by, for example, three or more kinds of precursor gases like in the first embodiment. Specifically, for example, like in a film forming apparatus 1D illustrated in FIG. 7, by performing the atomic layer deposition with the three kinds of precursor gases 10A, 10B, and 10C by using the three kinds of ALD heads 11A (12A), 11B (12B), and 11C (12C), a desired thin film may be formed.

Also in the embodiment, the inside of the chamber 10 may be set in vacuum atmosphere or atmosphere which is the same as the normal outside air in some cases in a manner similar to the first embodiment. Alternatively, the chamber 10 itself may not be provided.

### Third Embodiment

Subsequently, a third embodiment of the invention will be described. The same reference numerals are designated to the same components as those of the foregoing first and second embodiments, and repetitive description will not be given.

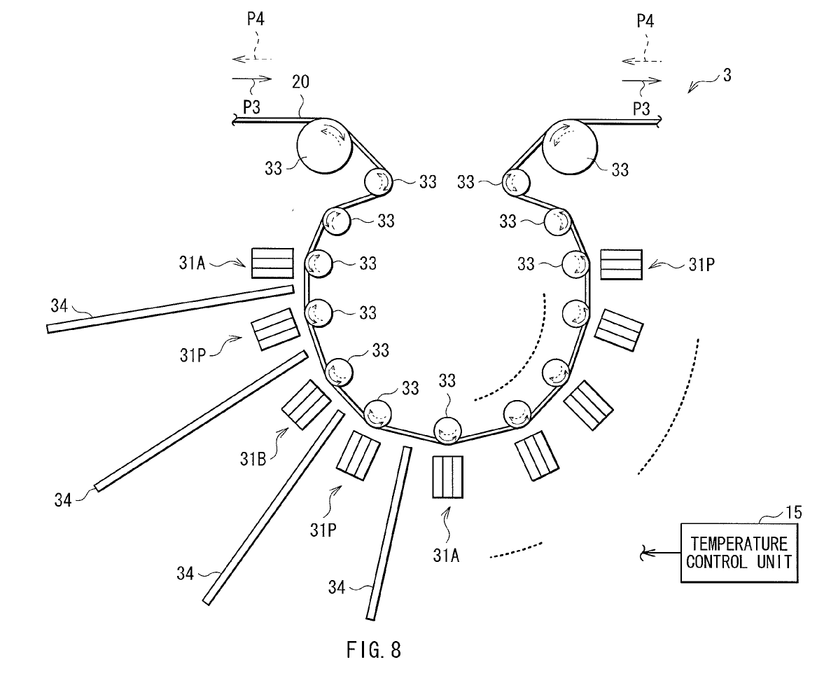

FIG. 8 illustrates a schematic configuration of a film forming apparatus (film forming apparatus 3) according to a third embodiment. The film forming apparatus 3 of the embodiment forms a film on a face on one side of the base material 20 like the film forming apparatus 1 of the first embodiment. Different from the film forming apparatus 1, the film forming apparatus 3 is not provided with the chamber 10 dedicated to store the purge gas 10P or the like, and performs purge process by using an ALD head 31P described below.

The film forming apparatus 3 has ALD heads 31A, 31B, and 31P, guide rolls 33, shields 34, and the temperature control section 15. Since a film forming method (thin film forming method) according to the third embodiment is embodied in the film forming apparatus 3 of the embodiment, it will be also described below.

The ALD heads 31A and 31B play rolls similar to those of the ALD heads 11A (12A) and 11B (12B), respectively. Specifically, the ALD head 31A is a gas source capable of outputting the precursor gas 10A for performing the atomic layer deposition to the base material 20, and outputs (injects) the precursor gas 10A from a not-shown output nozzle. The ALD head 31B is a gas source capable of outputting the precursor gas 10B for performing the atomic layer deposition to the base material 20, and outputs (injects) the precursor gas 10B from a not-shown output nozzle.

The ALD head 31P is a gas source capable of locally outputting the purge gas 10P to the base material 20 and is an ALD head dedicated to purging.

A plurality of the guide rolls 33 are provided in an annular shape. By the plurality of guide rolls 33 and not-shown feed rolls and take-up rolls, a conveying mechanism for conveying the base material 20 in the direction indicated by the arrow P3 in FIG. 8 is constructed. By such a conveying mechanism, the base material 20 may be conveyed in both directions indicated by arrows P3 and P4. In other words, the conveying mechanism may convey the base material 20 bidirectionally for the positions of the ALD heads 31A, 31B, and 31P. The arrows in the solid lines illustrated in the guide rolls 33 in FIG. 8 indicate the rotation directions of the guide rolls 33 when the base material 20 is conveyed in the direction of the arrow P3. The arrows in broken lines indicate the rotation directions of the guide rolls 33 when the base material 20 is conveyed in the direction of the arrow P4.

Also in the embodiment, like in the first and second embodiments, the ALD heads 31A and 31B are disposed so as to face the guide rolls 33. In other words, by the ALD head 31A or 31B and the guide roll 33, a member set (first member set) for performing the atomic layer deposition by outputting the precursor gas 10A or 10B to the face (surface) of one of the sides of the base material 20 is constructed. With the configuration, also in the third embodiment, in a manner similar to the first and second embodiments, the precursor gases 10A and 10B are locally output to the base material 20.

In the third embodiment, the ALD heads 31P are also disposed so as to individually face the guide rolls 33. Specifically, by the ALD heads 31P and the guide rolls 33, a member set (third member set) for performing the purge process by outputting the purge gas 10P to the surface of the base material 20 is constructed. With the configuration, in the embodiment, the purge gas 10P is locally output to the base material 20.

The shields 34 shield the gases by partitioning the regions of adjacent ALD heads.

In the embodiment, the temperature control section 15 adjusts (sets) the temperature of each of the guide rolls 33. Consequently, while adjusting the temperature of each of the guide rolls 33, films are formed by the atomic layer deposition on the base material 20.

Also in the embodiment with such a configuration, a similar effect is obtained by the action similar to that of the first embodiment. Specifically, the amount of the precursor gases 10A and 10B used is reduced more than that in the related art, the variety of kinds of usable precursor gases is widened, and while suppressing production cost, the degree of freedom in film formation is improved.

Particularly, in the embodiment, the purge process is performed by using the ALD heads 31P capable of locally outputting the purge gas 10P to the base material 20 without providing a dedicated chamber for storing the purge gas 10P or the like. Consequently, the amount of the purge gas 10P used is reduced more than that in the first and second embodiments. Therefore, in the embodiment, the production cost is further suppressed.

Modification of Third Embodiment

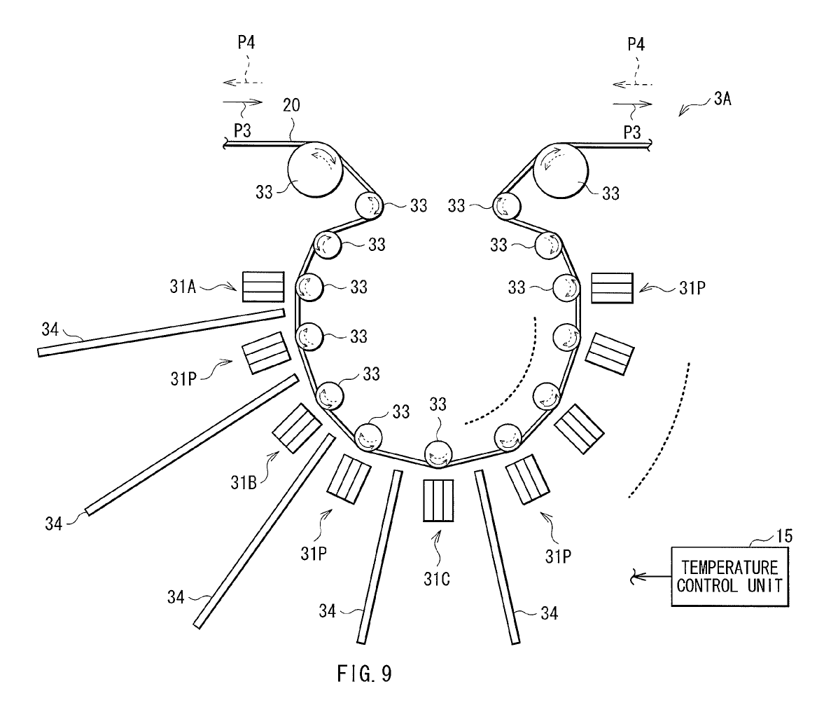

Also in the third embodiment, in a manner similar to the first embodiment, the atomic layer deposition may be performed with, for example, precursor gases of three kinds or more. Specifically, for example, like a film forming apparatus 3A illustrated in FIG. 9, by performing the atomic layer deposition with three kinds of precursor gases 10A, 10B, and 10C by using the three kinds of ALD heads 31A, 31B, and 31C, a desired thin film may be formed.

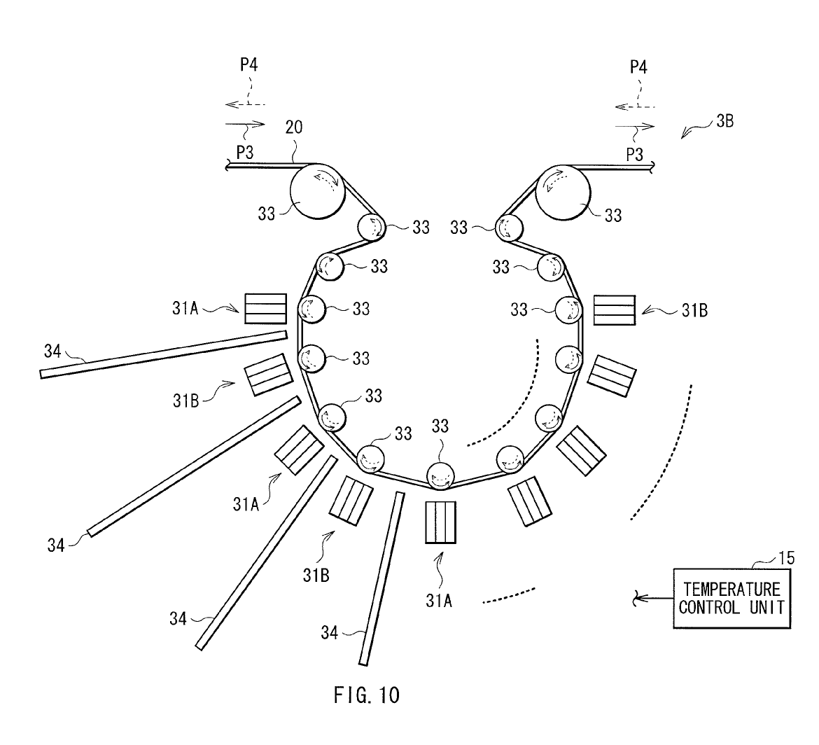

Also in the embodiment, in some cases, like a film forming apparatus 3B illustrated in FIG. 10, the ALD heads 31P are not provided and the purge process may not be performed.

### Fourth Embodiment

Subsequently, a fourth embodiment of the invention will be described. The same reference numerals are designated to the same components as those of the foregoing first to third embodiments, and repetitive description will not be given.

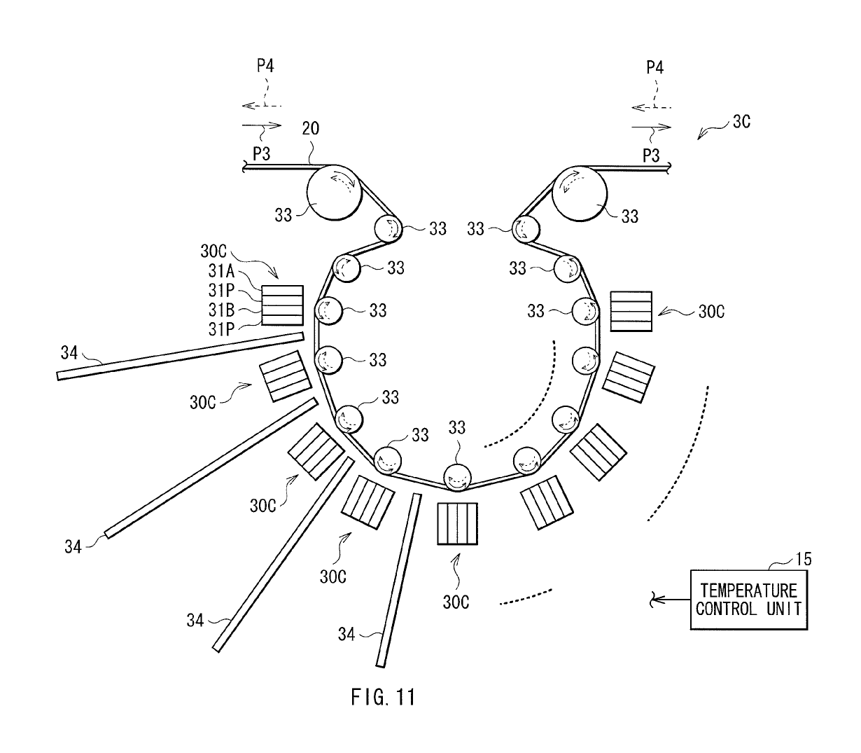

FIG. 11 illustrates a schematic configuration of a film forming apparatus (film forming apparatus 3C) according to a fourth embodiment. The film forming apparatus 3C of the embodiment corresponds to an apparatus obtained by making the film forming apparatus 3 of the third embodiment output a plurality of kinds of gases from the ALD heads. Since a film forming method (thin film forming method) according to the fourth embodiment is embodied in the film forming apparatus 3C of the embodiment, it will be also described below.

The film forming apparatus 3C is obtained by forming the single ALD head 30C by integrating the ALD heads 31A, 31B, and 31P in the film forming apparatus 3. Concretely, the ALD head 30C is constructed by disposing the ALD heads 31A, 31P, 31B, and 31P in this order along the conveyance direction of the base material 20 (the direction indicated by the arrow P3 in FIG. 11). In the ALD head 30C, the precursor gases 10A, 10B, and 10P are output from the ALD heads 31A, 31B, and 31P, respectively.

With such a configuration, the fourth embodiment obtains the following effect in addition to the effect of the third embodiment. Specifically, as compared with the third embodiment, the length of the output nozzle for each of the gases along the conveyance direction of the base material 20 is set shorter, so that the thickness of each of the precursor layers and, further, the monolayers is set to be smaller.

Modification of Fourth Embodiment

Also in the fourth embodiment, in a manner similar to the first embodiment, the atomic layer deposition may be performed with, for example, precursor gases of three kinds or more.

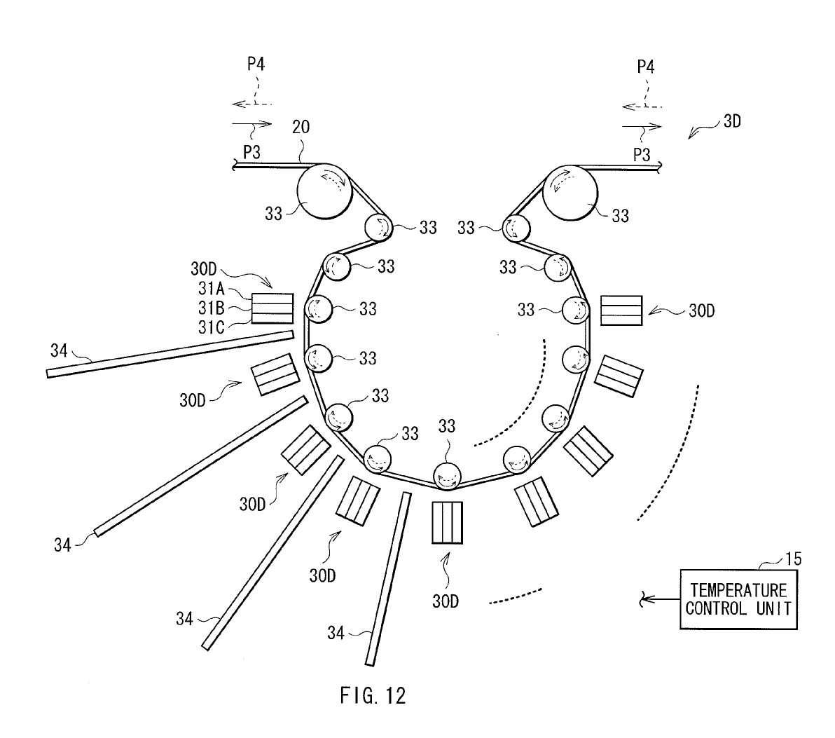

Also in the embodiment, in some cases, like a film forming apparatus 3D illustrated in FIG. 12, the ALD heads 31P are not provided in each of the ALD heads 30D and the purge process may not be performed.

Other Modifications

Although the present invention has been described above by some embodiments and modifications, the invention is not limited to the embodiments and the like, and various modifications may be possible.

For example, the invention is not limited to the materials, thickness of the layers, the film forming methods, the film formation parameters, and the like described in the embodiments and the like. The other materials and thickness may be employed or other film forming methods and film formation parameters may be used. Concretely, for example, in the case of doping a film formed by using an ALD head with an additive in a different process, a doping gas (dopant gas) may be preliminarily mixed in addition to a precursor gas (material gas) in a predetermined ALD head. With such a configuration, a doping process performed as a different process after film formation becomes unnecessary.

In the film forming apparatuses (film forming methods) of the present invention, preferably, the ALD heads and the guide rolls operate independently of each other. Even if an ALD head breaks down, since the guide rolls function normally, a film may be formed normally by the system as a whole. In the case of forming films successively by using a plurality of kinds of ALD heads like in the embodiments and the like, the following method is preferable so that films are stacked in desired order. Concretely, for example, like in the modification of the third embodiment, in the case of repeating the atomic layer deposition with the three kinds of precursor gases 10A, 10B, 10C, 10A, 10B, 10C, . . . by using the repetition mechanism of the three kinds of the ALD heads 31A, 31B, 31C, 31A, 31B, 31C, . . . , if the n-th ALD head 31A fails, film formation has to be stopped in the same n-th ALD heads 31B and 31C so that a desired film formation order is obtained. It is sufficient to perform the film formation in the desired film formation order by using the (n+1)th ALD head.

The film forming apparatus (film forming method) of the present invention are applicable to, for example, formation of thin films made of various materials written in the following table 5. Thin films obtained as described above are applicable to various films such as high-barrier films and multi-function films (such as conduction barrier films).

TABLE 5
Oxides

| | |
|---|---|
| Dielectrics (insulators) | Al₂O₃, TiO₂, ZrO₂, HfO₂, Ta₂O₅, Nb₂O₅, Sc₂O₃, Y₂O₃, |
| | MgO, B₂O₃, SiO₂, GeO₂, La₂O₃, CeO₂, PrOₓ, Nd₂O₃, |
| | Sm₂O₃, EuOₓ, Gd₂O₃, Dy₂O₃, Ho₂O₃, Er₂O₃, Tm₂O₃, |
| | Yb₂O₃, Lu₂O₃, SrTiO₃, BaTiO₃, PbTiO₃, PbZrO₃, |
| | BiₓTi_{y}O, BiₓSi_{y}O, SrTa₂O₆, SrBi₂Ta₂O₉, YScO₃, |
| | LaAlO₃, NdAlO₃, GdScO₃, LaScO₃, LaLuO₃, |
| | Er₃Ga₅O₁₃ |
| Conductors/ | In₂O₃, In₂O₃:Sn, In₂O₃:F, In₂O₃:Zr, SnO₂, |
| semiconductors | SnO₂:Sb, ZnO, ZnO:Al, ZnO:B, |
| | ZnO:Ga, RuO₂, RhO₂, IrO₂, Ga₂O₃, V₂O₅, WO₃, W₂O₃, |
| | NiO, FeOₓ, CrOₓ, |
| | CoOₓ, MnOₓ |
| Others | LaCoO₃, LaNiO₃, LaMnO₃, La₁₋ₓCaₓMnO₃ |

Nitrides

| | |
|---|---|
| Semiconductors/ | BN, AlN, GaN, InN, SiNₓ, Ta₃N₅, Cu₃n, Zr₃N₄, Hf₃N₄ |
| Insulators | |
| Metals | TiN, Ti—Si—N, Ti—Al—N, TaN, NbN, MoN, WNₓ, WNₓCy |

Others

| | |
|---|---|
| II-VI group | ZnS, ZnSe, ZnTe, |
| compounds | CaS, SrS, BaS, |
| | CdS, CdTe, MnTe, HgTe |
| TFEL phosphor | ZnS:M (M = Mn, Tb, Tm), |
| (II-VI group | CaS:M (M = Eu, Ce, Tb, Pb), |
| compounds) | SrS:M(M = Ce, Tb, Pb) |
| III-V group | GaAs, AlAs, AlP, InP, GaP, InAs |
| compounds | |
| fluorides | CaF₂, SrF₂, MgF₂, LaF₃, ZnF₂ |
| Simple substances and | Ru, Pt, Ir, Pd, Rh, Ag, W, Cu, Co, Fe, Ni, Mo, Ta, Ti, |
| elements | Al, Si, Ge |
| Others | La₂S₃, PbS, In₂S₃, CuₓS, CuGaS₂, Y₂O₂S, WS₂, TiS₂, |
| | SiC, TiCₓ, TaCₓ, WCₓ, Caₓ(PO₄)y, CaCO₃ |

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

The application is claimed as follows:

1. A film forming apparatus comprising:
a conveying mechanism including a plurality of roll members and conveying a base material as a member on which a film is to be formed; and
a plurality of heads disposed so as to individually face the roll members and each serving as a gas source capable of locally outputting a precursor gas for performing atomic layer deposition (ALD) to the base material.

2. The film forming apparatus according to claim 1, further comprising a temperature control section for individually adjusting temperatures of the roll members.

3. The film forming apparatus according to claim 1, wherein each of the heads are capable of individually outputting a plurality of kinds of precursor gases.

4. The film forming apparatus according to claim 1, wherein each of the heads outputs one kind of a precursor gas.

5. The film forming apparatus according to claim 1, further comprising a gas mechanism for exposing the base material to a predetermined purge gas between an operation of outputting one precursor gas and an operation of outputting another precursor gas by the head.

6. The film forming apparatus according to claim 5, wherein the gas mechanism is constructed by a head for purging as a gas source capable of locally outputting the purge gas to the base material.

7. The film forming apparatus according to claim 1, wherein member sets each made of the roll member and the head disposed so as to face each other include
a first member set for performing the atomic layer deposition by outputting the precursor gas to a face on one side of the base material, and
a second member set for performing the atomic layer deposition by outputting the precursor gas to a face on the other side of the base material.

8. The film forming apparatus according to claim 1, wherein the head performs the atomic layer deposition by using three kinds or more of precursor gases.

9. The film forming apparatus according to claim 1, wherein the conveying mechanism conveys the base material bidirectionally with respect to positions of the heads.

10. A film forming method of forming a film by atomic layer deposition (ALD) the method comprising, while conveying a base material as a member on which a film is to be formed by using a plurality of roll members, locally outputting a precursor gas to the base material by a plurality of heads as gas sources disposed so as to individually face the roll members.

11. The film forming method according to claim 10, wherein film formation is performed by the atomic layer deposition while individually adjusting temperatures of the roll members.
